(19) United States
(12) Patent Application Publication
(10) Pub. No.: US 2026/0371762 A1
(43) Pub. Date: Nov. 19, 2026

(54) SOLID-STATE IMAGING DEVICE

(71) Applicant: SONY SEMICONDUCTOR SOLUTIONS CORPORATION, Kanagawa (JP)

(72) Inventors: Yasuhiro NONAKA, Kanagawa (JP); Kentaro AKIYAMA, Kanagawa (JP)

(73) Assignee: SONY SEMICONDUCTOR SOLUTIONS CORPORATION, Kanagawa (JP)

(21) Appl. No.: 19/126,367

(22) PCT Filed: Sep. 25, 2023
(86) PCT No.: PCT/JP2023/034719

§ 371 Date: May 1, 2025

(30) Foreign Application Priority Data
Nov. 11, 2022 (JP) 2022-181092

(51) Int. Cl. H10F 39/00

(52) U.S. Cl. CPC H10F 39/807

(57) ABSTRACT

A solid-state imaging device includes: a semiconductor layer including a first semiconductor region of a first conductivity type, and a second semiconductor region of a second conductivity type in an imaging region in which a plurality of first photoelectric conversion elements that converts light into electric charges is arrayed, the second conductivity type being an opposite type of the first conductivity type; an insulator disposed on a first surface of the semiconductor layer on a light incident side; a first guard ring disposed in the insulator along an outer perimeter of the imaging region that contains a metal material, and electrically coupled to the first semiconductor region of the semiconductor layer; and a separation insulator disposed in the semiconductor layer along the outer perimeter of the imaging region and along an inner perimeter of the first guard ring, and electrically separating the first guard ring from the second semiconductor region.

### TECHNICAL FIELD

The present disclosure relates to a solid-state imaging device.

### BACKGROUND ART

Patent Literature 1 discloses a backside illumination solid-state imaging device. In the solid-state imaging device, photoelectric conversion units that convert incident light into electric charges are arrayed in an imaging region of a semiconductor layer. On an incident light side, a lens material and the like are formed via a passivation film. Additionally, in the solid-state imaging device, a guard ring is disposed along an outer perimeter of an imaging region and along an inner perimeter of a dicing line. The guard ring is formed in the passivation film with use of a metal material formed in the imaging region. The guard ring is then electrically coupled to a semiconductor layer, and the guard ring has a fixed potential. According to the solid-state imaging device having such a configuration, it is possible to effectively suppress or prevent entry of moisture from the dicing line side to the imaging region side, which makes it possible to increase moisture resistance.

### CITATION LIST

### Patent Literature

Patent Literature 1: Japanese Patent Application Laid-Open No. 2020-61476

### SUMMARY OF THE INVENTION

In the solid-state imaging device disclosed in the above-mentioned Patent Literature 1, an n-type semiconductor substrate is used as the semiconductor layer. A p-type semiconductor region (p-type well region) that constitutes a photoelectric conversion unit is formed in the imaging region of the n-type semiconductor substrate. Furthermore, a p-type carrier region (hole layer) as a pinning layer is formed on a surface of the semiconductor layer on the light incident side from the imaging region to the outer perimeter of the imaging region. Meanwhile, the guard ring is electrically coupled to the n-type semiconductor substrate without intervention of the p-type carrier region. When the solid-state imaging device is on standby, power at a voltage of 0 V or less is supplied to the p-type semiconductor region, and power at a voltage exceeding 0 V is supplied to the n-type semiconductor substrate. Hence, a short circuit between different power supplies when the n-type semiconductor region, the guard ring, and the p-type semiconductor region (p-type carrier region) serve as a short circuit path has been desired to be effectively suppressed or prevented.

A solid-state imaging device according to a first embodiment of the present disclosure includes: a semiconductor layer including a first semiconductor region of a first conductivity type, and a second semiconductor region of a second conductivity type in an imaging region in which a plurality of first photoelectric conversion elements that converts light into electric charges is arrayed, the second conductivity type being an opposite type of the first conductivity type; an insulator disposed on a first surface of the semiconductor layer on a light incident side; a first guard ring that is disposed in the insulator along an outer perimeter of the imaging region, that includes a metal material, and that is electrically coupled to the first semiconductor region of the semiconductor layer; and a separation insulator that is disposed in the semiconductor layer along the outer perimeter of the imaging region and along an inner perimeter of the first guard ring, and that electrically separates the first guard ring from the second semiconductor region.

In a solid-state imaging device according to a second embodiment of the present disclosure, a carrier layer of the second conductivity type is formed in a portion of the first surface of the semiconductor layer between the second semiconductor region and the first guard ring, the carrier region being shallower in junction depth than the second semiconductor region, and the separation insulator is formed to have such a depth as to divide at least the carrier layer, in the solid-state imaging device according to the first embodiment.

In a solid-state imaging device according to a third embodiment of the present disclosure, the separation insulator is disposed so as to penetrate the semiconductor layer from the first surface to a second surface facing the first surface in the solid-state imaging device according to the first embodiment.

### BRIEF DESCRIPTION OF THE DRAWINGS

FIG. 1 is a longitudinal cross-sectional diagram illustrating a main section of a solid-state imaging device according to a first embodiment of the present disclosure (a cross-sectional view along an A-A section line illustrated in FIG. 2).

FIG. 2 is a planar configuration diagram illustrating an overall configuration of the solid-state imaging device illustrated in FIG. 1.

FIG. 3 is an enlarged longitudinal cross-sectional diagram illustrating a region B surrounded by broken lines illustrated in FIG. 1.

FIG. 4 is a longitudinal cross-sectional diagram illustrating the main section of the solid-state imaging device illustrated in FIG. 1 during a wafer manufacturing process (before a scribing process).

FIG. 5 is a longitudinal sectional diagram illustrating a main section of a solid-state imaging device according to a second embodiment of the present disclosure (a cross-sectional view along a C-C section line illustrated in FIG. 6) and corresponding to FIG. 1.

FIG. 6 is a planar configuration diagram illustrating an overall configuration of the solid-state imaging device illustrated in FIG. 5 and corresponding to FIG. 2.

FIG. 7 is a longitudinal sectional diagram illustrating a main section of a solid-state imaging device according to a third embodiment of the present disclosure (a cross-sectional view along a D-D section line illustrated in FIG. 8) and corresponding to FIG. 1.

FIG. 8 is a planar configuration diagram illustrating an overall configuration of the solid-state imaging device illustrated in FIG. 7 and corresponding to FIG. 2.

FIG. 9 is a longitudinal sectional diagram illustrating a main section of a solid-state imaging device according to a fourth embodiment of the present disclosure (a cross-sectional view along an E-E section line illustrated in FIG. 10) and corresponding to FIG. 1.

FIG. 10 is a planar configuration diagram illustrating an overall configuration of the solid-state imaging device illustrated in FIG. 9 and corresponding to FIG. 2.

FIG. 11 is a longitudinal sectional diagram illustrating a main section of a solid-state imaging device according to a fifth embodiment of the present disclosure (a cross-sectional view along an F-F section line illustrated in FIG. 12) and corresponding to FIG. 1.

FIG. 12 is a planar configuration diagram illustrating an overall configuration of the solid-state imaging device illustrated in FIG. 11 and corresponding to FIG. 2.

FIG. 13 is a longitudinal sectional diagram illustrating a main section of a solid-state imaging device according to a sixth embodiment of the present disclosure (a cross-sectional view along a G-G section line illustrated in FIG. 14) and corresponding to FIG. 1.

FIG. 14 is a planar configuration diagram illustrating an overall configuration of the solid-state imaging device illustrated in FIG. 13 and corresponding to FIG. 2.

FIG. 15 is a longitudinal sectional diagram illustrating a main section of a solid-state imaging device according to a seventh embodiment of the present disclosure (a cross-sectional view along an H-H section line illustrated in FIG. 16) and corresponding to FIG. 1.

FIG. 16 is a planar configuration diagram illustrating an overall configuration of the solid-state imaging device illustrated in FIG. 15 and corresponding to FIG. 2.

FIG. 17 is a block diagram depicting an example of schematic configuration of a vehicle control system.

FIG. 18 is a diagram of assistance in explaining an example of installation positions of an outside-vehicle information detecting section and an imaging section.

### MODES FOR CARRYING OUT THE INVENTION

Some embodiments of the present disclosure will be described below in detail with reference to drawings. Note that the description will be given in the following order.

### 1. First Embodiment

In a first embodiment, a description will be given of a first example to which the present technique is applied to a solid-state imaging device. In the first embodiment, the solid-state imaging device is a backside illumination solid-state imaging device. Additionally, in the first embodiment, a description will be given of a longitudinal cross-sectional configuration including a guard ring in the solid-state imaging device, a planar configuration, and a longitudinal cross-sectional configuration during a manufacturing process.

### 2. Second Embodiment

In a second embodiment, a description will be given of a second example in which a structure of the guard ring is changed in the solid-state imaging device according to the first embodiment.

### 3. Third Embodiment

In a third embodiment, a description will be given of a third example in which the structure of the guard ring is changed in the solid-state imaging device according to the first embodiment.

### 4. Fourth Embodiment

In a fourth embodiment, a description will be given of a fourth example in which a first semiconductor element is mounted on a light incident surface side in the solid-state imaging device according to the second embodiment.

### 5. Fifth Embodiment

In a fifth embodiment, a description will be given of a fifth example in which a second semiconductor element is mounted on the opposite side of the light incident surface side in the solid-state imaging device according to the second embodiment.

### 6. Sixth Embodiment

In a sixth embodiment, a description will be given of a sixth example in which a third semiconductor element is further mounted on the second semiconductor element in the solid-state imaging device according to the fifth embodiment.

### 7. Seventh Embodiment

In a seventh embodiment, a description will be given of a seventh example in which the semiconductor device according to the fifth embodiment further includes two types of photoelectric conversion elements in an imaging region.

### 8. Application Example of Application to Moving Object

In this application example, a description will be given of an example in which the present technique is applied to a vehicle control system as one example of a moving object control system.

### 9. Other Embodiments

### 1. First Embodiment

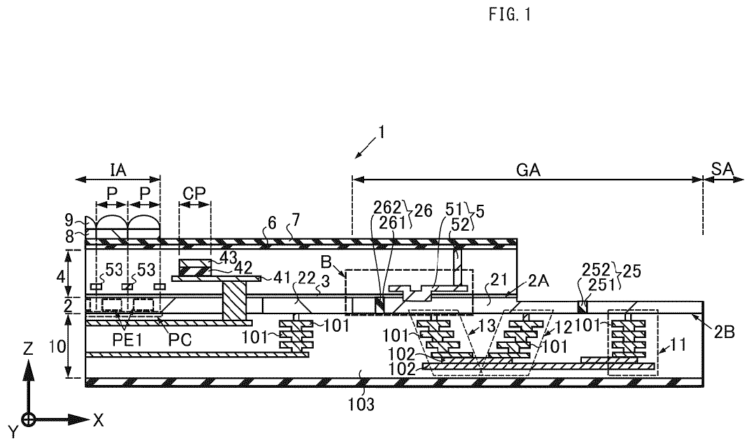

A solid-state imaging device 1 according to a first embodiment of the present disclosure will be described with reference to FIGS. 1 to 4. An X arrow direction illustrated in the drawings represents, as appropriate, one planar direction of the solid-state imaging device 1 placed on a plane for convenience sake. A Y arrow direction represents another planar direction orthogonal to the X arrow direction. In addition, a Z arrow direction represents an upper direction orthogonal to the X arrow direction and the Y arrow direction. That is, the X arrow direction, the Y arrow direction, and the Z arrow direction respectively coincide with an X axis direction, a Y axis direction, and a Z axis direction in a three-dimensional coordinate system. Note that each of these directions is illustrated for easier understanding of the description, and does not limit a direction of the present technique.

### Configuration of Solid-State Imaging Device 1

### (1) Overall Configuration of Solid-State Imaging Device 1

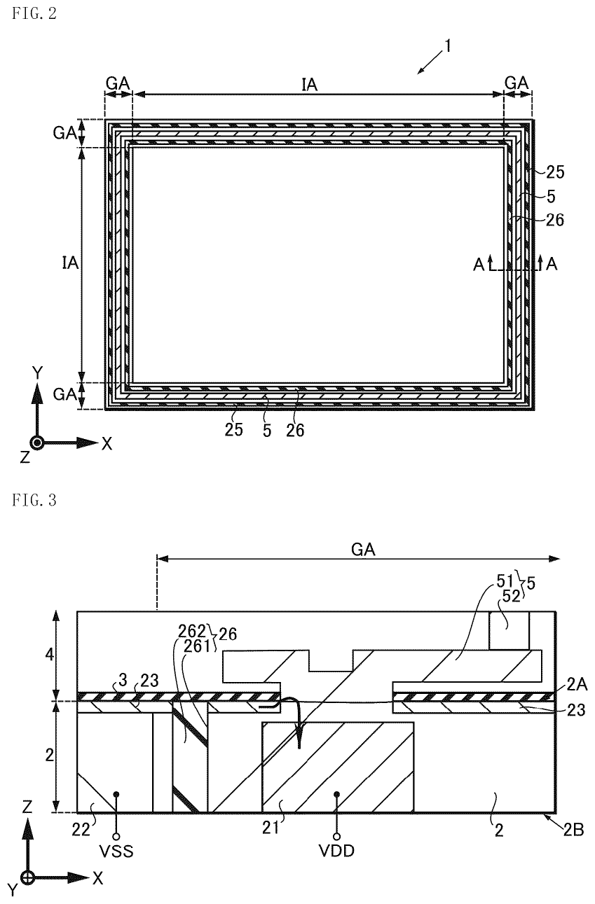

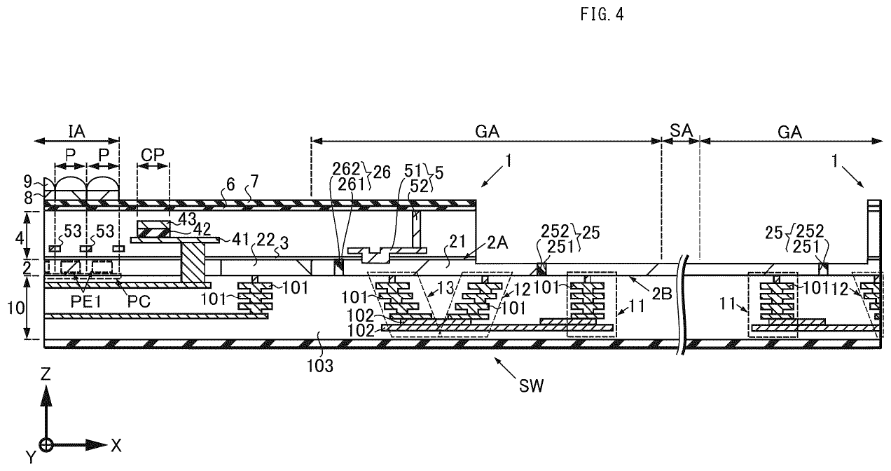

FIG. 1 illustrates an example of a longitudinal cross-sectional configuration of a peripheral region of the solid-state imaging device 1 according to the first embodiment. FIG. 2 illustrates an example of an overall planar configuration of the solid-state imaging device 1 illustrated in FIG. 1. FIG. 3 illustrates an example of a longitudinal cross-sectional configuration of a main section illustrated in FIG. 1. Additionally, FIG. 4 illustrates an example of a longitudinal cross-sectional configuration of the peripheral region during a manufacturing process of the solid-state imaging device 1 (before a step of dicing a semiconductor wafer).

As illustrated in FIGS. 1 to 3, the solid-state imaging device 1 according to the first embodiment is constructed as a backside illumination solid-state imaging device. More specifically, the solid-state imaging device 1 is constructed as a complementary metal-oxide semiconductor (CMOS) image sensor. The solid-state imaging device 1 includes a semiconductor layer 2, an insulator 4, a first guard ring 5, and a separation insulator 26 as main constituent elements. Details will be described below.

### (2) Configuration of Semiconductor Layer 2

As illustrated in FIGS. 1 to 3, the solid-state imaging device 1 includes the semiconductor layer 2. The semiconductor layer 2 is formed to include, for example, a single-crystal silicon (Si) substrate. More specifically, for example, an n-type semiconductor substrate as a first conductivity type with a low impurity concentration is used in the semiconductor layer 2.

As illustrated in FIG. 2, the semiconductor layer 2 is formed to be a rectangular shape when viewed from the Z arrow direction (hereinafter simply referred to as “in a plan view”). Although the shape is not particularly limited, the semiconductor layer 2 is formed to have a rectangular shape as a planar shape. The solid-state imaging device 1 as a final product is formed to have a planar shape that is substantially same as the planar shape of the semiconductor layer 2.

An imaging region IA is disposed in a middle portion of the solid-state imaging device 1. The imaging region IA occupies a major portion of the solid-state imaging device 1, and is formed to have a shape that is similar to and slightly smaller than the planar shape of the semiconductor layer 2 in the plan view.

As illustrated in FIG. 1, in the imaging region IA, a plurality of first photoelectric conversion elements PE1 that converts light into electric charges is arrayed in the semiconductor layer 2. Although a detailed description about an array configuration is omitted, the plurality of first photoelectric conversion elements PE1 is regularly arrayed in each of the X arrow direction and the Y arrow direction. Although a detailed description about a cross-sectional structure is omitted, the first photoelectric conversion element PE1 is formed to include, for example, a photodiode. Hence, in the semiconductor layer 2, a p-type semiconductor region (p-type well region) 22 that constitutes photodiodes is formed in the imaging region IA. The p-type semiconductor region 22 is of a second conductivity type that is an opposite type of the first conductivity type. The p-type semiconductor region 22, the p-type well region, or a carrier region 23 corresponds to a “second semiconductor region of the second conductivity type” according to the present technique. Power VSS is supplied to the p-type semiconductor region 22 when the solid-state imaging device 1 is on standby. For example, power at a voltage of 0 [V] or less is used as the power VSS.

As illustrated in FIGS. 1 and 2, a guard ring region GA is disposed in an outer perimeter of the imaging region IA in the solid-state imaging device 1. The guard ring region GA is formed at an outermost edge portion of the semiconductor layer 2 along each side of the planar rectangular shape. In other words, the guard ring region GA is formed to have a rectangular ring shape in the plan view. In other words, the guard ring region GA is disposed along the outer perimeter of the imaging region IA, and is disposed in an inner perimeter of a scribing region SA that exists during the manufacturing process of the solid-state imaging device 1.

FIG. 4 illustrates the semiconductor layer 2 during the manufacturing process of the solid-state imaging device 1. The semiconductor layer 2 is in a state of a semiconductor wafer SW before a scribing process (before a dicing process). In this semiconductor layer 2, a plurality of solid-state imaging devices 1 is formed with the scribing region SA interposed therebetween. For example, electric characteristics of the plurality of solid-state imaging devices 1 are inspected in the state of the semiconductor wafer SW. Thereafter, the semiconductor layer 2 is cut in the scribing region SA, and singulated to individual solid-state imaging devices 1 as dies or semiconductor chips.

In the guard ring region GA, an n-type semiconductor region (n-type well region) 21 is disposed in the semiconductor layer 2. The n-type semiconductor region 21 is formed to be of a conductivity type that is same as that of the semiconductor layer 2, but is formed at an impurity concentration that is higher than that of the semiconductor layer 2. The n-type semiconductor region 21 or the n-type semiconductor substrate corresponds to a “first semiconductor region of the first conductivity type” according to the present technique. Power VDD is supplied to the n-type semiconductor region 21 when the solid-state imaging device 1 is on standby. For example, power at a voltage exceeding 0 [V] is used as the power VDD. Note that constituent elements disposed in the guard ring GA such as the first guard ring 5 will be described later.

As illustrated in FIGS. 2 and 3, a pinning film (charge fixed film) 3 is disposed on a first surface 2A of the semiconductor layer 2 on the light incident side from the imaging region IA to the guard ring region GA. The carrier region (carrier accumulation region) 23 is formed on a portion of the first surface 2A of the semiconductor layer 2 in contact with a pinning film 3.

In the pinning film 3, for example, a metal oxide material containing one or more kinds selected from hafnium oxide (HfO₂), zirconium oxide (ZrO₂), aluminum oxide (Al₂O₃), titanium oxide (TiO₂), and tantalum oxide (Ta₂O₅) is used. The carrier region 23 is electrically coupled to the p-type semiconductor region 22 formed in the imaging region IA of the semiconductor layer 2, and extends over the guard ring region GA. The carrier region 23 mentioned herein is a hole accumulation region. A junction depth of the carrier region 23 is shallower than a junction depth of the p-type semiconductor region 22. Furthermore, an impurity concentration in the carrier region 23 is higher than an impurity concentration in the p-type semiconductor region 22.

### (2) Configuration of Insulator 4

As illustrated in FIG. 2, the insulator 4 is disposed on the first surface 2A of the semiconductor layer 2 via the pinning film 3. The insulator 4 is formed to include a plurality of insulation layers in reality. The insulator 4 is used as an interlayer insulation film or a passivation film for insulation and separation of wiring 41, a metal layer 42, a metal layer 43, and the like. In other words, the insulator 4 is used as a waveguide that guides incident light to the first photoelectric conversion element PE1 in the imaging region IA and also constitutes a wiring layer. The insulator 4 includes, for example, silicon oxide (SiO₂) or the like.

The metal layers 42 and 43 illustrated in FIG. 2 are disposed in the peripheral region of the imaging region IA and on the inner perimeter of the guard ring region GA. The metal layer 43 is formed to be in contact with the metal layer 42, and is electrically coupled to the metal layer 42. The metal layers 42 and 43 are used as a coupling terminal CP. The coupling terminal CP is used, for example, when a first semiconductor element 31 of a solid-state imaging device 1 according to a fourth embodiment is mounted. The first semiconductor element 31 will be described later. For example, a metal material such as cobalt (Co) is used for the metal layer 42. Additionally, a metal material such as copper (Cu) is used for the metal layer 43.

The wiring 41 is formed to be in contact with the metal layer 42. The metal layer 42 is electrically coupled to the wiring 41. The wiring 41 includes penetrating wiring that penetrates the semiconductor layer 2 in a thickness direction, and is coupled to a pixel circuit PC disposed on a second surface 2B side of the semiconductor layer 2. For example, a metal material such as Cu is used for the wiring 41.

### (4) Configuration of Pixel P

As illustrated in FIGS. 1 and 2, a plurality of pixels P is disposed in the imaging region IA. Although a detailed structure is not illustrated, the pixel P includes the first photoelectric conversion element PE1, an optical filter 8, and an optical lens 9 as main constituent elements.

The optical filter 8 is disposed with respect to the semiconductor layer 2 on the first surface 2A side via the insulator 4, an insulation film 6, and a protection film 7. The optical filter 8 includes, for example, a total of three-colored color filters that are different in color on a pixel P-by-pixel P basis. That is, the optical filter 8 includes a red light filter that causes light in a red light wavelength range to pass therethrough, a green light filter that causes light in a green light wavelength range to pass therethrough, and a blue light filter that causes light in a blue light wavelength range to pass therethrough. The optical filter 8 includes, for example, a resin material that contains a dye. The insulation film 6 mentioned herein includes, for example, an insulation material such as silicon nitride (SiN). Additionally, the protection film 7 includes, for example, an insulation material such as SiO₂.

The optical lens 9 is disposed on the optical filter 8 on the opposite side of the first photoelectric conversion element PE1. In other words, the optical lens 9 is disposed on the optical filter 8 on the light incident side. Although not illustrated in the plan view, the optical lens 9 is formed to have a circular shape on the pixel P-by-pixel P basis. Additionally, the optical lens 9 is formed to have a curved shape so as to be curved toward the light incident side when viewed in the Y arrow direction on the pixel P-by-pixel P basis (hereinafter referred to as in a “side view”), and condenses incident light in the first photoelectric conversion element PE1. The optical lens 9 is formed as a so-called on-chip lens, and is formed on the pixel P-by-pixel P basis or integrally formed over a plurality of pixels P. The optical lens 9 includes, for example, a transparent resin material.

Additionally, in the imaging region, a separator between pixels 53 is disposed between the pixels P. The separator between pixels 53 is formed on the pinning film 3 on the opposite side of the semiconductor layer 2, and is formed as a light-shielding member that optically separates the pixels P therebetween. For example, a metal material such as tungsten (W) that is excellent in light blocking property is used for the separator between pixels 53.

### (5) Configuration of Pixel Circuit PC

As illustrated in FIG. 1, the pixel circuit PC is electrically coupled to one pixel Por a plurality of pixels P via a transfer transistor, which is not illustrated. Although a detailed circuit configuration of the pixel circuit PC and a longitudinal cross-sectional configuration of the pixel circuit PC in a plan view are neither described nor illustrated, the pixel circuit PC is configured to include a plurality of transistors. For example, the pixel circuit PC includes transistors used for a reset transistor, an amplification transistor, a selection transistor, and the like. The transistors including the transfer transistor and constituting the pixel circuit PC are formed to include, for example, an insulated gate field-effect transistor (IGFET) of an n-channel conductivity type. The pixel circuit PC is disposed on a main surface portion of the semiconductor layer 2 on the second surface 2B side.

### (6) Configuration of Wiring Layer 10

A wiring layer 10 is disposed on the second surface 2B side of the semiconductor layer 2 so as to cover the pixel circuit PC. For example, multi-layer wiring 101 or the like is formed in the wiring layer 10. The multi-layer wiring 101 connects the plurality of transistors that constitutes the pixel circuit PC. For example, a metal wiring material such as copper (Cu) is used for the wiring 101. Although an illustration is simplified, an insulator 103 is formed between the multi-layer wiring 101 and the multi-layer wiring 101 or the like. The insulator 103 is formed to include a multi-layer insulation film in reality. The insulator 103 includes, for example, SiO₂.

In the solid-state imaging device 1, the pixel circuit PC and coupling wires thereof (for example, the wiring 101 and the like) are disposed on the second surface 2B side of the semiconductor layer 2. In contrast, the optical lens 9, the optical filter 8, and the first photoelectric conversion element PE1 are disposed on the light incident side, and a structure of not blocking incident light is adopted. That is, the solid-state imaging device 1 is constructed as a backside illumination solid-state imaging device.

### (7) Configurations of Second Guard Rind 25 and Third Guard Rings 11 to 13

As illustrated in FIGS. 1, 2, and 4, the solid-state imaging device 1 according to the first embodiment includes, in addition to the first guard ring 5, a second guard ring 25 and third guard rings 11 to 13. First, the second guard ring 25 is described.

### (7-1) Configuration of Second Guard Rind 25

The second guard ring 25 is disposed in the semiconductor layer 2 along the outer perimeter of the first guard ring 5. More specifically, the second guard ring 25 is disposed so as to be further adjacent to the scribing region SA and along the inner perimeter of the scribing region SA. The second guard ring 25 is configured to include a penetrating groove 251 and an embedded insulator 252.

The penetrating groove 251 is formed as a groove that extends along the outer perimeter of the first guard ring 5 in each of the X arrow direction and the Y arrow direction and that surrounds the imaging region IA without an end. The penetrating groove 251 is formed as a penetrating groove that penetrates the semiconductor layer 2 in the thickness direction from the first surface 2A of the semiconductor layer 2 to the second surface 2B of the semiconductor layer 2. The penetrating groove 251 has a groove width of, for example, 0.1 μm or more and 0.5 μm or less. The embedded insulator 252 is embedded in the penetrating groove 251. The embedded insulator 252 includes, for example, an inorganic insulation material such as SiO₂ or SiN. Note that in a region in which the second guard ring 25 is disposed, the pinning film 3, the insulator 4, the insulation film 6, and the protection film 7 are removed before the dicing process, and do not exist as a final product.

With the inclusion of the second guard ring 25 configured in this manner, it is possible to effectively suppress or prevent chipping of a diced end face in the dicing process. Additionally, with the inclusion of the second guard ring 25, it is possible to effectively suppress or prevent moisture from transmitting through the first surface 2A of the semiconductor layer 2 and gaining entry. Furthermore, with the inclusion of the second guard ring 25, it is possible to electrically separate between the semiconductor layer 2 on the scribing region SA side and the semiconductor layer 2 on the imaging region IA side with the second guard ring 25 serving as a boundary.

### (7-2) Configuration of Third Guard Rings 11 to 13

The third guard rings 11 to 13 are sequentially disposed in the wiring layer 10 in the guard ring region GA from the scribing region SA to the imaging region IA. The third guard rings 11 to 13 are disposed along the outer perimeter of the imaging region IA.

The third guard ring 11 is disposed the closest to the scribing region SA in the wiring layer 10. With use of the multi-layer wiring 101 and the wiring 102 each disposed in the imaging region IA, the third guard ring 11 is formed by lamination of the multi-layer wiring 101 and the wiring 102 in the thickness direction of the wiring layer 10. For example, a metal wiring material such as an aluminum (Al)—Cu alloy is used for the wiring 102. The use of the wiring 101 and the wiring 102 mentioned herein means forming the third guard ring 11 with use of an identical wiring material in an identical layer of each of the wiring 101 and the wiring 102 in an identical manufacturing process.

The third guard ring 12 is disposed in the wiring layer 10 along the inner perimeter of the third guard ring 11. With use of the multi-layer wiring 101 and the wiring 102 each disposed in the imaging region IA, the third guard ring 12 is formed by lamination of the multi-layer wiring 101 and the wiring 102 in the thickness direction of the wiring layer 10, similarly to the third guard ring 11.

The third guard ring 13 is disposed the closest to the imaging region IA in the wiring layer 10 along the inner perimeter of the third guard ring 12. With use of the multi-layer wiring 101 and the wiring 102 each disposed in the imaging region IA, the third guard ring 13 is formed by lamination of the multi-layer wiring 101 and the wiring 102 in the thickness direction of the wiring layer 10, similarly to the third guard ring 11.

With the inclusion of the third guard rings 11 to 13 configured in this manner, it is possible to effectively suppress or prevent moisture from transmitting through especially the inside of the wiring layer 10 and gaining entry into the imaging region IA side.

### (7-3) Configuration of First Guard Rind 5

As illustrated in FIGS. 1 to 4, the first guard ring 5 is disposed in the insulator 4 along the outer perimeter of the imaging region IA. More specifically, the first guard ring 5 is disposed closer to the imaging region IA than the second guard ring 25, the third guard ring 11, and the third guard ring 12 are to the imaging region IA, and is disposed in a region that is equivalent to the third guard ring 13. The first guard ring 5 is constructed to include a first metal layer 51 and a second metal layer 52.

With use of the separator between pixels 53, the first metal layer 51 is formed on the pinning film 3 on the opposite side of the semiconductor layer 2. Since the separator between pixels 53 is used for the first metal layer 51, the first metal layer 51 includes a metal material such as W. A portion of the first metal layer 51 is electrically coupled to the n-type semiconductor substrate serving as the semiconductor layer 2 through a contact hole formed in the pinning film 3 (refer to especially FIG. 3). A reference sign of the contact hole is omitted. Since the pinning film 3 is removed in a coupling region between the first metal layer 51 and the semiconductor layer 2, the carrier region 23 is not formed in this region.

The second metal layer 52 is disposed in the insulator 4, coupled to the first metal layer 51, and extends in the thickness direction of the insulator 4. The second metal layer 52 here includes a metal material that is similar to that of the first metal layer 51.

With the inclusion of the first guard ring 5 configured in this manner, it is possible to effectively suppress or prevent moisture from transmitting through especially the inside of the insulator 4 and an interface between the insulator 4 and the semiconductor layer 2 and gaining entry into the imaging region IA side.

### (8) Configuration of Separation Insulator 26

As illustrated in FIGS. 1 to 4, especially in FIG. 3, the separation insulator 26 is disposed in the semiconductor layer 2 along the outer perimeter of the imaging region IA and along the inner perimeter of the first guard ring 5. The separation insulator 26 is formed to have such a depth from the first surface 2A as to divide at least the carrier region 23. In other words, the separation insulator 26 is formed to have such a depth as to be same as a depth of pn junction between the carrier region 23 and the n-type semiconductor substrate in the semiconductor layer 2 or larger than the depth of the pn junction.

In the solid-state imaging device 1 according to the first embodiment, the separation insulator 26 is configured to include a penetrating groove 261 and an embedded insulator 262. The penetrating groove 261 is formed as a groove that extends along the inner perimeter of the first guard ring 5 in each of the X arrow direction and the Y arrow direction and that surrounds the imaging region IA without an end. The penetrating groove 261 is formed as a penetrating groove that penetrates the semiconductor layer 2 in the thickness direction from the first surface 2A of the semiconductor layer 2 to the second surface 2B of the semiconductor layer 2. The penetrating groove 261 has a groove width of, for example, 0.1 μm or more and 0.5 μm or less.

The penetrating groove 261 mentioned herein is formed to have an identical or substantially identical groove width from the first surface 2A of the semiconductor layer 2 to the second surface 2B of the semiconductor layer 2. That is, the separation insulator 26 is formed to have, as a cross-section shape, a rectangular shape, more specifically, a rectangular parallelepiped shape in a side view. In the present technique, the penetrating groove 261 may be formed to have a groove width that linearly or gradually decreases from the first surface 2A of the semiconductor layer 2 to the second surface 2B of the semiconductor layer 2. The separation insulator 26 formed in this manner is formed to have, as a cross-section shape, an inverted trapezoid shape in a side view. The embedded insulator 262 is embedded in the penetrating groove 261. The embedded insulator 262 includes, for example, an inorganic insulation material such as SiO₂ or SiN.

That is, in the solid-state imaging device 1 according to the first embodiment, the separation insulator 26 is formed to have a cross-section structure that is same as that of the second guard ring 25. In other words, in a method of manufacturing the solid-state imaging device 1, the separation insulator 26 is formed in a manufacturing process that is same as that of forming the second guard ring 25. Note that the groove width of the penetrating groove 261 in the separation insulator 26 may be different in dimension from the groove width of the penetrating groove 251 in the second guard ring 25.

### Workings and Effects

The solid-state imaging device 1 according to the first embodiment includes the semiconductor layer 2, the insulator 4, the first guard ring 5, and the separation insulator 26 as illustrated in FIGS. 1 to 4. The semiconductor layer 2 includes the n-type semiconductor region (first semiconductor region) 21 of the first conductivity type, and the p-type semiconductor region (second semiconductor region) 22 of the second conductivity type in the imaging region IA in which the plurality of first photoelectric conversion elements PE1 that converts light into electric charges is arrayed. The second conductivity type is the opposite type of the first conductivity type. The insulator 4 is disposed on the first surface 2A of the semiconductor layer 2 on the light incident side. The first guard ring 5 is disposed in the insulator 4 along the outer perimeter of the imaging region IA. The first guard ring 5 includes a metal material, and is electrically coupled to the n-type semiconductor region 21 of the semiconductor layer 2. Here, the separation insulator 26 is disposed in the semiconductor layer 2 along the outer perimeter of the imaging region IA and along the inner perimeter of the first guard ring 5. The separation insulator 26 electrically separates the first guard ring 5 from the p-type semiconductor region 22. In the solid-state imaging device 1 configured in this manner, when it is on standby, power VSS at a voltage of 0 [V] or less is supplied to the p-type semiconductor region 22, and power VDD at a voltage exceeding 0 [V] is supplied to the n-type semiconductor region (n-type semiconductor substrate) 21. The separation insulator 26 is disposed between the imaging region IA and the first guard ring 5 and electrically separates the first guard ring 5 from the p-type semiconductor region 22. As a result, it is possible to effectively suppress or prevent a short circuit between different power supplies (VSS-VDD) when the n-type semiconductor region 21, the first guard ring 5, and the p-type semiconductor region 22 serve as a short circuit path.

Additionally, in the solid-state imaging device 1, especially illustrated in FIG. 3, the carrier region 23 of the second conductivity type is formed in a portion of the first surface 2A of the semiconductor layer 2 between the p-type semiconductor region 22 and the first guard ring 5. A junction depth of the carrier region 23 is shallower than a junction depth of the p-type semiconductor region 22. The separation insulator 26 is then formed to have such a depth as to divide at least the carrier region 23. This makes it possible for the separation insulator 26 to electrically separate the first guard ring 5 from the p-type semiconductor region 22. As a result, it is possible to effectively suppress or prevent a short circuit between different power supplies when the n-type semiconductor region 21, the first guard ring 5, and the p-type semiconductor region 22 serve as a short circuit path.

Additionally, in the solid-state imaging device 1, as illustrated in especially FIG. 3, the separation insulator 26 is disposed so as to penetrate the semiconductor layer 2 from the first surface 2A to the second surface 2B facing the first surface 2A. This makes it possible for the separation insulator 26 to electrically and physically separate the first guard ring 5 from the p-type semiconductor region 22. As a result, it is possible to effectively suppress or prevent a short circuit between different power supplies when the n-type semiconductor region 21, the first guard ring 5, and the p-type semiconductor region 22 serve as a short circuit path.

Additionally, the solid-state imaging device 1 includes the second guard ring 25 as illustrated, especially in FIGS. 1, 2, and 4. The second guard ring 25 is disposed in the semiconductor layer 2 along the outer perimeter of the first guard ring 5. In other words, the second guard ring 25 is disposed along the inner perimeter of the scribing region SA. Additionally, the second guard ring 25 is disposed to penetrate the semiconductor layer 2 from the first surface 2A to the second surface 2B. As illustrated in FIGS. 1 to 4, the separation insulator 26 is formed to have a cross-section structure that is same as that of the second guard ring 25. As a result, the separation insulator 26 is formed with use of the second guard ring 25, which makes it possible to easily form the separation insulator 26.

In other words, the separation insulator 26 is formed in the manufacturing process that is same as the manufacturing process of forming the second guard ring 25 of the solid-state imaging device 1. As a result, it is possible to reduce the number of processes of manufacturing the solid-state imaging device 1 in comparison with a case where a process of forming the separation insulator 26 is different from a process of forming the second guard ring 25.

Additionally, in the solid-state imaging device 1, the first guard ring 5 includes W, as illustrated in FIGS. 1, 3, and 4. Since W is used for the separator between pixels 53 in the imaging region IA, it is possible to easily form the first guard ring 5. In other words, since the first guard ring 5 is formed with use of the process of forming the separator between pixels 53, it is possible to reduce the number of processes of manufacturing the solid-state imaging device 1.

Additionally, in the solid-state imaging device 1, the separation insulator 26 includes at least one kind of an inorganic insulation material that is selected from SiO₂ and SiN as illustrated in especially FIG. 3. Since the inorganic insulation material is an insulation material with high reliability in semiconductor technologies, it is possible to easily form the separation insulator 26.

Furthermore, the solid-state imaging device 1 includes the pixel P in which the optical filter 8 and the optical lens 9 are sequentially disposed with respect to the first surface 2A of the semiconductor layer 2 via the insulator 4 in a region corresponding to the first photoelectric conversion element PE1 as illustrated in FIGS. 1 and 4. Meanwhile, the solid-state imaging device 1 includes the pixel circuit PC on the second surface 2B side facing the first surface 2A of the semiconductor layer 2. The pixel circuit PC processes a charge transferred from the first photoelectric conversion element PE1. That is, the solid-state imaging device 1 has a backside illumination structure. As a result, it is possible to effectively suppress or prevent a short circuit between different power supplies when the n-type semiconductor region 21, the first guard ring 5, and the p-type semiconductor region 22 serve as a short circuit path.

### 2. Second Embodiment

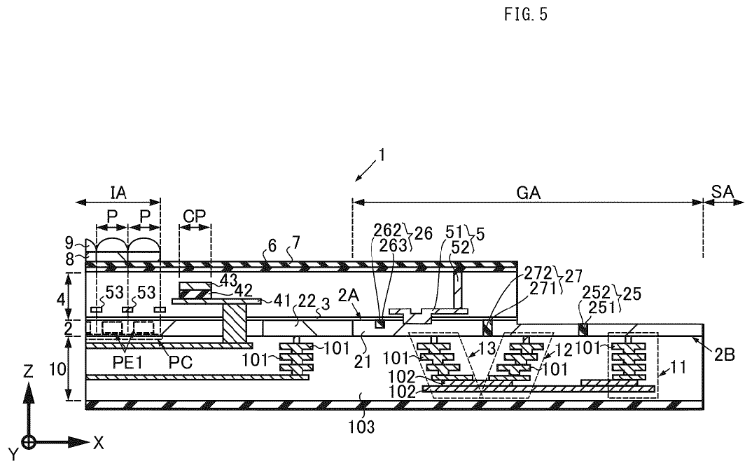

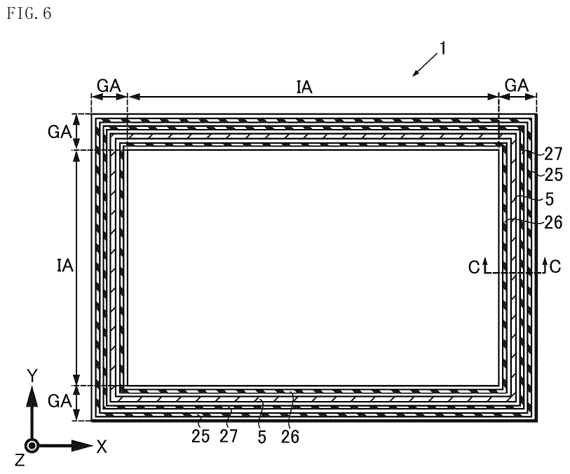

A solid-state imaging device 1 according to a second embodiment of the present disclosure will be described with reference to FIGS. 5 and 6. Note that, in the second embodiment and subsequent embodiments, a constituent element that is identical or substantially same as that of the solid-state imaging device 1 according to the first embodiment is denoted by an identical sign, and an overlapping description is omitted.

### Configuration of Solid-State Imaging Device 1

FIG. 5 illustrates an example of a longitudinal cross-sectional configuration of a peripheral region of the solid-state imaging device 1 according to the second embodiment. FIG. 6 illustrates an example of an overall planar configuration of the solid-state imaging device 1 illustrated in FIG. 5.

### (1) Configuration of Second Guard Rind 27

As illustrated in FIGS. 5 and 6, in the solid-state imaging device 1 according to the second embodiment, a plurality of second guard rings 25 and 27 is arrayed along the outer perimeter of the first guard ring 5 in the solid-state imaging device 1 according to the first embodiment.

More specifically, the second guard ring 25 is adjacent to the scribing region SA and is disposed along the inner perimeter of the scribing region SA. Meanwhile, a second guard ring 27 is disposed along the inner perimeter of the second guard ring 25. The second guard ring 27 is disposed in the insulator 4 and is configured to include a penetrating groove 271 and an embedded insulator 272.

The penetrating groove 271 is formed as a groove that extends along the outer perimeter of the first guard ring 5 in each of the X arrow direction and the Y arrow direction and that surrounds the imaging region IA without an end. The penetrating groove 271 is formed as a penetrating groove that penetrates the semiconductor layer 2 in the thickness direction from the first surface 2A of the semiconductor layer 2 to the second surface 2B of the semiconductor layer 2 similarly to the penetrating groove 251. The embedded insulator 272 is embedded in the penetrating groove 271. The embedded insulator 272 includes, for example, an inorganic insulation material, similarly to the embedded insulator 252. That is, the second guard ring 27 is formed to have a longitudinal cross-section structure that is identical or substantially same as that of the second guard ring 25.

With the inclusion of the second guard rings 25 and 27 configured in this manner, it is possible to further effectively suppress or prevent chipping. Additionally, with the inclusion of the second guard rings 25 and 27, it is possible to further effectively suppress or prevent moisture from transmitting through the first surface 2A of the semiconductor layer 2 and gaining entry. Furthermore, with the inclusion of the second guard rings 25 and 27, it is possible to electrically separate between the semiconductor layer 2 on the scribing region SA side and the semiconductor layer 2 on the imaging region IA side with the second guard rings 25 and 27 serving as a boundary. Note that the second guard ring 27 may be used as a guard ring that surrounds the outer perimeter of the coupling terminal CP.

### (2) Configuration of Separation Insulator 26

Additionally, in the solid-state imaging device 1 according to the second embodiment, the separation insulator 26 is configured to include a groove 263 and an embedded insulator 262. Details are as follows. The groove 263 is formed as a groove that extends along the inner perimeter of the first guard ring 5 in each of the X arrow direction and the Y arrow direction and that surrounds the imaging region IA without an end. The groove 263 is dug deep in the thickness direction of the semiconductor layer 2 from the first surface 2A of the semiconductor layer 2 to the second surface 2B of the semiconductor layer 2, but does not penetrate the second surface 2B. The groove 263 is formed to have such a depth from the first surface 2A as to divide at least the carrier region 23. In other words, the separation insulator 26 is formed to have such a depth as to be same as a depth of pn junction between the carrier region 23 and the n-type semiconductor substrate in the semiconductor layer 2 or larger than the depth of the pn junction. The embedded insulator 262 is embedded in the groove 263. The embedded insulator 262 includes an inorganic insulation material similarly to the embedded insulator 262 of the solid-state imaging device 1 according to the first embodiment.

Here, the groove 263 is formed to have an identical or substantially identical groove width from the first surface 2A of the semiconductor layer 2 toward the second surface 2B side of the semiconductor layer 2. That is, the separation insulator 26 is formed to have, as a cross-section shape, a rectangular shape, more specifically, a rectangular parallelepiped shape in a side view. In the present technique, the groove 263 may be formed to have a groove width that linearly or gradually decreases from the first surface 2A of the semiconductor layer 2 toward the second surface 2B side of the semiconductor layer 2. The separation insulator 26 formed in this manner is formed to have, as a cross-section shape, an inverted trapezoid shape in a side view.

Constituent elements other than the above-mentioned constituent elements are identical or substantially same as those of the above-mentioned solid-state imaging device 1 according to the first embodiment.

### Workings and Effects

In the solid-state imaging device 1 according to the second embodiment, it is possible to obtain workings and effects similar to those obtained by the solid-state imaging device 1 according to the first embodiment.

### 3. Third Embodiment

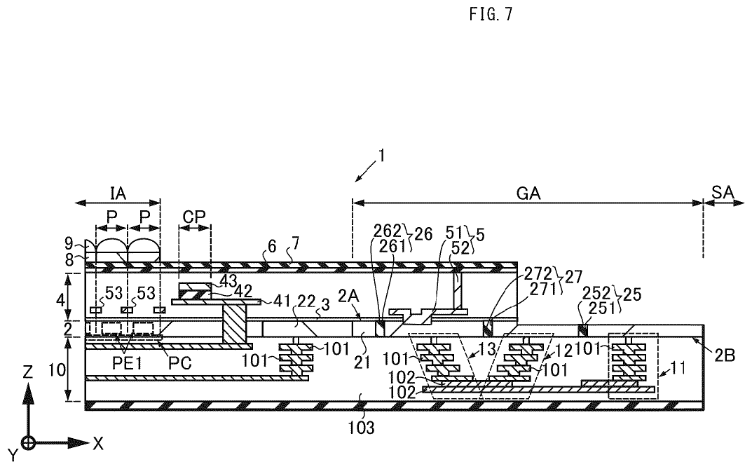

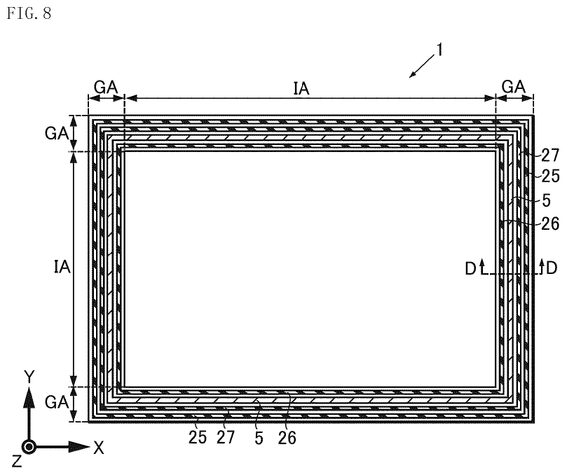

A solid-state imaging device 1 according to a third embodiment of the present disclosure will be described with reference to FIGS. 7 and 8.

### Configuration of Solid-State Imaging Device 1

FIG. 7 illustrates an example of a longitudinal cross-sectional configuration of a peripheral region of the solid-state imaging device 1 according to the third embodiment. FIG. 8 illustrates an example of an overall planar configuration of the solid-state imaging device 1 illustrated in FIG. 7.

As illustrated in FIGS. 7 and 8, the solid-state imaging device 1 according to the third embodiment includes constituent elements that combine the solid-state imaging device 1 according to the first embodiment and the solid-state imaging device 1 according to the second embodiment. Details are as follows. In the solid-state imaging device 1, similarly to the solid-state imaging device 1 according to the second embodiment, the plurality of second guard rings 25 and 27 is disposed in the semiconductor layer 2 along the outer perimeter of the first guard ring 5.

Meanwhile, the separation insulator 26 is disposed in the semiconductor layer 2 along the inner perimeter of the first guard ring 5. Similarly to the separation insulator 26 of the solid-state imaging device 1 according to the first embodiment, the separation insulator 26 is configured to include the penetrating groove 261 and the embedded insulator 262. In other words, the separation insulator 26 is formed to have a longitudinal cross-section structure that is identical or substantially same as that of the second guard ring 25.

Constituent elements other than the above-mentioned constituent elements are identical or substantially same as those of the solid-state imaging device 1 according to the first embodiment or the second embodiment.

### Workings and Effects

In the solid-state imaging device 1 according to the third embodiment, it is possible to obtain workings and effects that combine the solid-state imaging device 1 according to the first embodiment and the solid-state imaging device 1 according to the second embodiment.

### 4 Fourth Embodiment

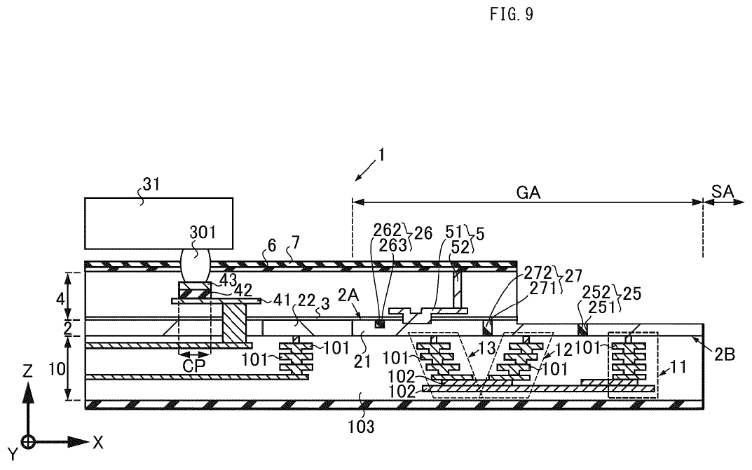

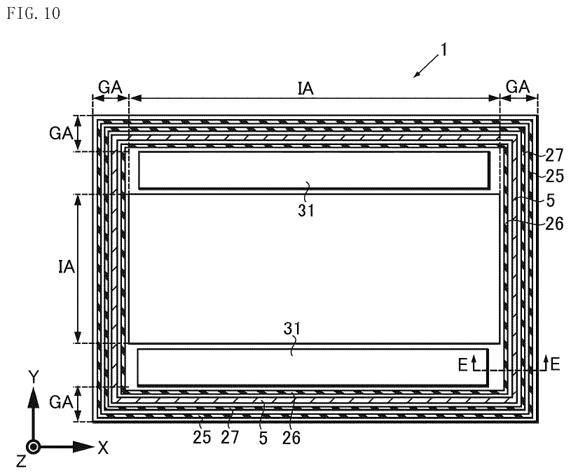

A solid-state imaging device 1 according to a fourth embodiment of the present disclosure will be described with reference to FIGS. 9 and 10.

### Configuration of Solid-State Imaging Device 1

FIG. 9 illustrates an example of a longitudinal cross-sectional configuration of a peripheral region of the solid-state imaging device 1 according to the fourth embodiment. FIG. 10 illustrates an example of an overall planar configuration of the solid-state imaging device 1 illustrated in FIG. 9.

As illustrated in FIGS. 9 and 10, in the solid-state imaging device 1 according to the fourth embodiment, the first semiconductor elements 31 are mounted to the first surface 2A of the semiconductor layer 2 in the outer perimeter of the imaging region IA via the insulator 4. Details are as follows.

As illustrated in FIG. 10, the first semiconductor element 31 is formed to have, as a planar shape, a rectangular shape in a plan view. A plane area (plane size) of the first semiconductor element 31 is smaller than a plane area (plane size) of the semiconductor layer 2 that serves as a mounting base. In the fourth embodiment, a total of two first semiconductor elements 31 are mounted along respective two facing sides in the Y arrow direction of the semiconductor layer 2 that is formed in the rectangular shape. Since such a layout is adopted, the first semiconductor element 31 is formed to have a rectangular shape with the X arrow direction serving as the longitudinal direction in a plan view. Note that the number of the first semiconductor elements 31 is not limited to two, and one or three or more first semiconductor elements 31 may be mounted.

As illustrated in FIG. 9, the first semiconductor element 31 (terminal whose illustration and reference sign are omitted) is electrically and mechanically coupled to the coupling terminal CP disposed on the first surface 2A side of the semiconductor layer 2. A bump electrode 301 is used for the coupling. A micro-bump electrode is used here as the bump electrode 301. For example, Sn-type solder such as a tin (Sn)-silver (Ag) alloy is used for the bump electrode 301. As a method of mounting the first semiconductor element 31, either a face-up method or a face-down method may be adopted.

A circuit that is electrically coupled to the pixel circuit PC is mounted on the first semiconductor element 31. The circuit is not illustrated. The circuit includes, for example, one or a plurality of logic circuits that constitutes a peripheral circuit of the backside illumination solid-state imaging device 1 and that is selected from a vertical driving circuit, a column signal processing circuit, a horizontal driving circuit, an output circuit, and a control circuit. The circuit is constructed to include, a transistor, a resistor, a capacitance, and the like, similarly to the pixel circuit PC.

Since the two first semiconductor elements 31 are mounted, the logic circuits that constitute the peripheral circuit are mounted on the respective circuits of the two first semiconductor elements 31 in a divided manner. Additionally, a portion of the logic circuits in the peripheral circuit may be mounted on the circuit of one of the two first semiconductor elements 31, and the other portion of the logic circuits in the peripheral circuit may be mounted on the circuit of the other of the first semiconductor elements 31.

Although a detailed description of a circuit configuration of the logic circuits is omitted, the above-mentioned control circuit receives an input clock and data that instructs an operation mode or the like, and outputs data such as internal information of the solid-state imaging device. That is, the control circuit generates a clock signal and a control signal that serve as a criterion for operations of the vertical driving circuit, the column signal processing circuit, the horizontal driving circuit, and the like, on the basis of a vertical synchronization signal, a horizontal synchronization signal, and a master clock. These signals are then input to the vertical driving circuit, the column signal processing circuit, and the horizontal driving circuit.

The vertical driving circuit is configured to include, for example, a shift register. The vertical driving circuit selects pixel driving wiring, and supplies a pulse for driving the pixels P to the selected pixel driving wiring. The pixels P are driven on a row-by-row basis. That is, the vertical driving circuit selectively scans the pixels P in the imaging region IA on the row-by-row basis in a sequential manner in a vertical direction. A signal charge generated according to an amount of received light in the first photoelectric conversion element PE1 in each pixel P is supplied to the column signal processing circuit as a pixel signal through the vertical signal line.

The column signal processing circuit is disposed, for example, for every column of the pixels P. The column signal processing circuit performs, on the pixel row-by pixel row basis, signal processing, such as removal of noise, on signals output from the pixels P in one row. That is, the column signal processing circuit performs signal processing such as correlated double sampling (CDS) to remove fixed pattern noise that is intrinsic to the pixel P, signal amplification, or analog-to-digital (AD) conversion. A horizontal selection switch is coupled to an output stage of the column signal processing circuit between the horizontal signal lines. The horizontal selection switch is not illustrated.

The horizontal driving circuit is configured to include, for example, a shift register. The horizontal driving circuit sequentially outputs a horizontal scanning pulse to sequentially select each column signal processing circuit, and outputs a pixel signal from each column signal processing circuit to the horizontal signal line.

The output circuit performs signal processing on a signal sequentially supplied from each column signal processing circuit through the horizontal signal line and outputs the signal. For example, in a case of performing only buffering, there is a case where the output circuit performs black level adjustment, column variation correction, various kinds of digital signal processing, or the like. Additionally, each logic circuit includes an input/output terminal, which is not illustrated. An input/output terminal communicates signals between the solid-state imaging device 1 and the outside of the solid-state imaging device 1.

Note that a memory circuit may be mounted on at least a portion of the circuit of the first semiconductor element 31. The memory circuit is used as, for example, a shift register.

Constituent elements other than the above-mentioned constituent elements are identical or substantially same as those of the above-mentioned solid-state imaging device 1 according to the second embodiment.

### Workings and Effects

In the solid-state imaging device 1 according to the fourth embodiment, it is possible to obtain workings and effects similar to those obtained by the solid-state imaging device 1 according to the second embodiment.

Additionally, in the solid-state imaging device 1, the first semiconductor elements 31 are mounted on the first surface 2A side of the semiconductor layer 2 in the outer perimeter of the imaging region IA as illustrated in FIGS. 9 and 10. A circuit that is electrically coupled to the pixel circuit PC is mounted on the first semiconductor element 31. Hence, it is possible to increase a package density in the thickness direction of the first semiconductor element 31, which makes it possible to increase a package density of the peripheral circuit including the circuit while extending the imaging region IA.

Additionally, in the solid-state imaging device 1, as illustrated in FIGS. 9 and 10, the plane area of the first semiconductor element 31 is smaller than the plane area of the semiconductor layer 2 when viewed from the thickness direction of the semiconductor layer 2. Hence, it is possible to further extend the imaging region IA of the solid-state imaging device 1.

Additionally, in the solid-state imaging device 1, the first semiconductor element 31 is mounted to the semiconductor layer 2 via the bump electrode 301 as illustrated in FIG. 9. In the solid-state imaging device 1 having such a configuration, the first semiconductor element 31 is mounted with use of the bump electrode 301, which makes it possible to make the area for mounting smaller than the area for mounting using for example, a wire bonding method. As a result, it is possible to increase a package density of the peripheral circuit including the circuit while extending the imaging region IA.

### 5. Fifth Embodiment

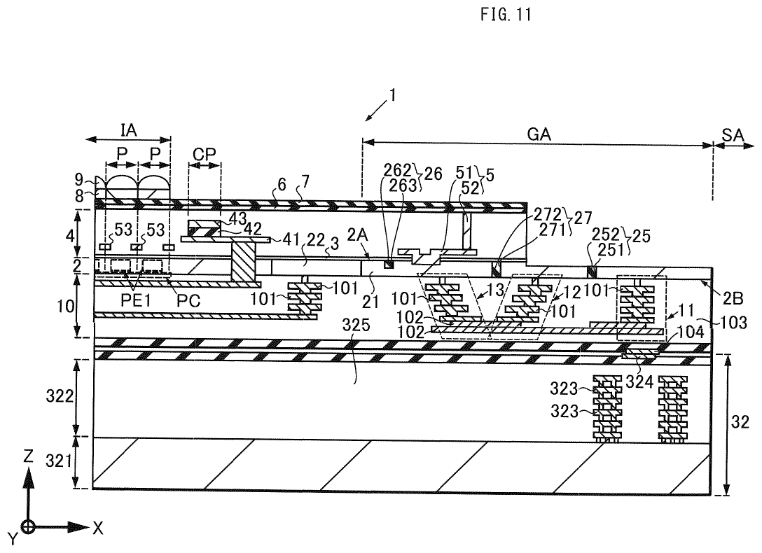

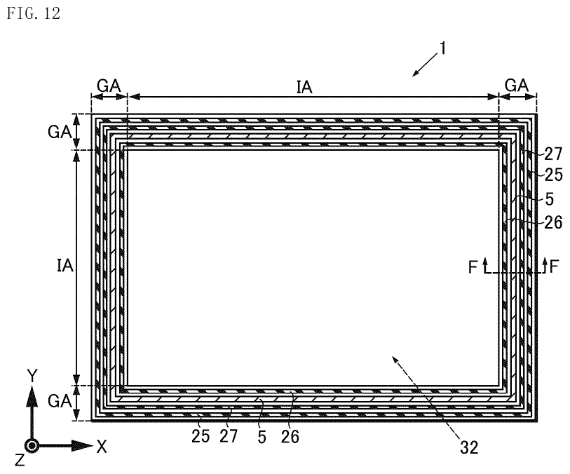

A solid-state imaging device 1 according to a fifth embodiment of the present disclosure will be described with reference to FIGS. 11 and 12.

### Configuration of Solid-State Imaging Device 1

FIG. 11 illustrates an example of a longitudinal cross-sectional configuration of a peripheral region of the solid-state imaging device 1 according to the fifth embodiment. FIG. 12 illustrates an example of an overall planar configuration of the solid-state imaging device 1 illustrated in FIG. 11.

As illustrated in FIGS. 11 and 12, the solid-state imaging device 1 according to the fifth embodiment is an application example of the solid-state imaging device 1 according to the fourth embodiment. Details are as follows. In the solid-state imaging device 1, a second semiconductor element 32 is mounted on the second surface 2B side of the semiconductor layer 2 in a region that overlaps the imaging region IA.

The second semiconductor element 32 is configured to include a semiconductor layer (semiconductor substrate) 321 and a wiring layer 322. Furthermore, a circuit that is similar to the circuit mounted on the first semiconductor element 31 of the solid-state imaging device 1 according to the fourth embodiment is mounted on the second semiconductor element 32. The circuit is not illustrated. That is, the circuit is electrically coupled to the pixel circuit PC.

The circuit, which is not illustrated, is formed on the pixel circuit PC side of the semiconductor layer 321. Multi-layer wiring 323 is disposed in the wiring layer 322. A terminal 324 is disposed on a top layer of the wiring layer 322 in the Z arrow direction. The terminal 324 includes, for example, a wiring material such as Cu. In the wiring layer 322, formed is an insulator 325 that electrically separates the multi-layer wiring 323, the terminal 324, and the like from each other.

Here, a terminal 104 is disposed on a top layer of the wiring layer 10 on the semiconductor layer 2 side on the second semiconductor element 32 side. The terminal 104 includes, for example, a wiring material such as Cu. The terminal 324 in the second semiconductor element 32 is joined with the terminal 104, the second semiconductor element 32 is mounted on the terminal 104, and the circuit in the second semiconductor element 32 is electrically coupled to the pixel circuit. Junction between the terminal 104 and the terminal 324 is so-called Cu—Cu junction.

Constituent elements other than the above-mentioned constituent elements are identical or substantially same as those of the above-mentioned solid-state imaging device 1 according to the fourth embodiment.

### Workings and Effects

In the solid-state imaging device 1 according to the fifth embodiment, it is possible to obtain workings and effects similar to those obtained by the solid-state imaging device 1 according to the fourth embodiment.

Additionally, in the solid-state imaging device 1, the second semiconductor element 32 is mounted on the second surface 2B side of the semiconductor layer 2 in the region that overlaps the imaging region IA as illustrated in FIGS. 11 and 12. The circuit that is electrically coupled to the pixel circuit PC is mounted on the second semiconductor element 32. Hence, it is possible to increase a package density of the peripheral circuit including the circuit while extending the imaging region IA.

### 6. Sixth Embodiment

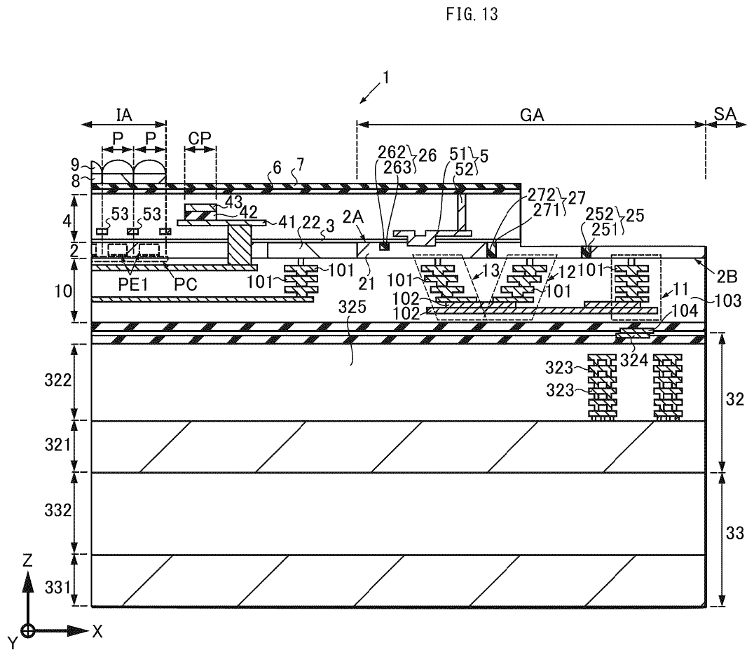

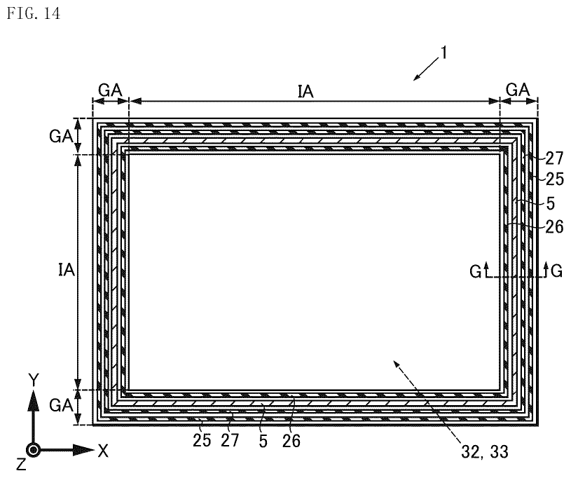

A solid-state imaging device 1 according to a sixth embodiment of the present disclosure will be described with reference to FIGS. 13 and 14.

### Configuration of Solid-State Imaging Device

FIG. 13 illustrates an example of a longitudinal cross-sectional configuration of a peripheral region of the solid-state imaging device 1 according to the sixth embodiment. FIG. 14 illustrates an example of an overall planar configuration of the solid-state imaging device 1 illustrated in FIG. 13.

As illustrated in FIGS. 13 and 14, the solid-state imaging device 1 according to the sixth embodiment is an application example of the solid-state imaging device 1 according to the fifth embodiment. Details are as follows. In the solid-state imaging device 1, a third semiconductor element 33 is further mounted on the second semiconductor element 32. The third semiconductor element 33 is mounted on the second semiconductor element 32 on the opposite side of the semiconductor layer 2. In other words, the second semiconductor element 32 and the third semiconductor element 33 are sequentially laminated and mounted to the semiconductor layer 2.

The third semiconductor element 33 is configured to include a semiconductor layer (semiconductor substrate) 331 and a wiring layer 332. A specific structure of the wiring layer 322 is identical or substantially same as the structure of the wiring layer 322, and thus a description thereof is omitted.

Additionally, a circuit that is similar to the circuit mounted on the first semiconductor element 31 of the solid-state imaging device 1 according to the fourth embodiment is mounted on the third semiconductor element 33. The circuit is not illustrated. That is, the circuit is electrically coupled to the pixel circuit PC. Logic circuits that constitute the peripheral circuit are mounted on the circuit in the second semiconductor element 32 and the circuit in the third semiconductor element 33 in a divided manner. Additionally, a portion of the logic circuits in the peripheral circuit may be mounted on the circuit in the second semiconductor element 32, and the other portion of the logic circuits in the peripheral circuit may be mounted on the circuit in the third semiconductor element 33. Note that, although not illustrated, the circuit in the second semiconductor element 32 and the circuit in the third semiconductor element are electrically coupled to each other via penetrating wiring that penetrates the semiconductor layer 321 of the second semiconductor element 32 in the thickness direction. Additionally, in the present technique, the logic circuit may be mounted on the second semiconductor element 32 and the memory circuit may be mounted on the third semiconductor element 33.

Constituent elements other than the above-mentioned constituent elements are identical or substantially same as those of the above-mentioned solid-state imaging device 1 according to the fifth embodiment.

### Workings and Effects

In the solid-state imaging device 1 according to the sixth embodiment, it is possible to obtain workings and effects similar to those obtained by the solid-state imaging device 1 according to the fifth embodiment.

Additionally, in the solid-state imaging device 1, the third semiconductor element 33 is mounted on the second semiconductor element 32 as illustrated in FIGS. 13 and 14. The circuit that is electrically coupled to the pixel circuit PC is mounted on the third semiconductor element 33. Hence, it is possible to further increase a package density of the peripheral circuit including the circuit while extending the imaging region IA.

### 7. Seventh Embodiment

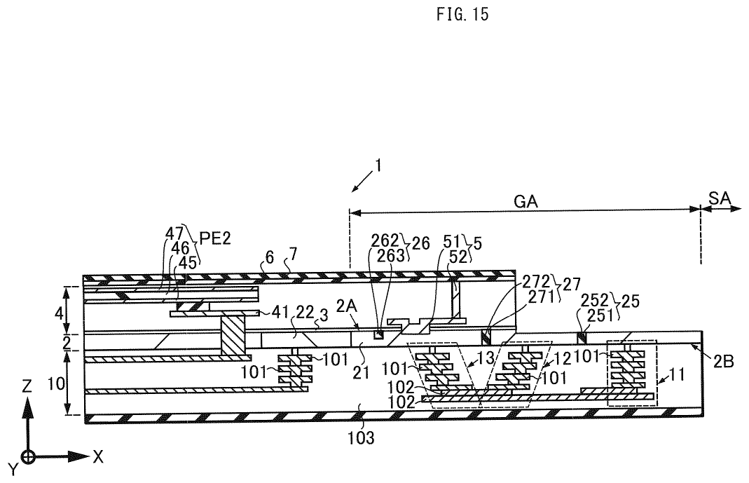

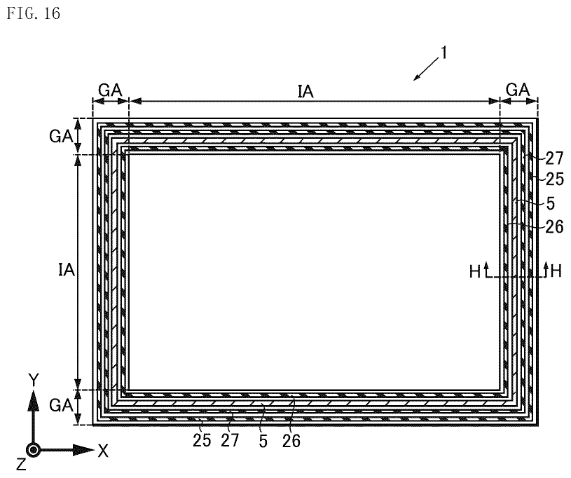

A solid-state imaging device 1 according to a sixth embodiment of the present disclosure will be described with reference to FIGS. 15 and 16.

### Configuration of Solid-State Imaging Device 1

FIG. 15 illustrates an example of a longitudinal cross-sectional configuration of a peripheral region of the solid-state imaging device 1 according to the seventh embodiment. FIG. 16 illustrates an example of an overall planar configuration of the solid-state imaging device 1 illustrated in FIG. 15.

As illustrated in FIGS. 15 and 16, the solid-state imaging device 1 according to the seventh embodiment is an application example of the solid-state imaging device 1 according to the fifth embodiment. Details are as follows. The solid-state imaging device 1 further includes, in addition to the first photoelectric conversion element PE1, a second photoelectric conversion element PE2 between the first photoelectric conversion element PE1 in the insulator 4 and the optical filter 8 in the imaging region IA. The second photoelectric conversion element PE2 is formed by sequential lamination of a first electrode 45, a photoelectric conversion layer 46, and a second electrode 47 in the Z arrow direction.

The first electrode 45 is disposed on the pixel P-by-pixel P basis, and includes, for example, a transparent electrode material. The photoelectric conversion layer 46 converts incident light into a charge. The photoelectric conversion layer 46 includes, for example, an organic photoelectric conversion material. That is, the second photoelectric conversion element PE2 mentioned herein is an organic photoelectric conversion element. The second electrode 47 is disposed in each of the plurality of pixels P, and formed to contain, for example, a transparent electrode material. Additionally, a charge accumulation transfer layer may be disposed between the first electrode 45 and the photoelectric conversion layer 46. The charge accumulation transfer layer includes, for example, an oxide semiconductor material. As the oxide semiconductor material, for example, IGZO containing indium (In), gallium (Ga), zinc (Zn), and oxygen (O) is used. Alternatively, as the oxide semiconductor material, it is possible to use IGSiO containing In, Ga, Si, and O, IAZO containing In, Al, Zn, and O, or the like.

Constituent elements other than the above-mentioned constituent elements are identical or substantially same as those of the above-mentioned solid-state imaging device 1 according to the fifth embodiment.

### Workings and Effects

In the solid-state imaging device 1 according to the seventh embodiment, it is possible to obtain workings and effects similar to those obtained by the solid-state imaging device 1 according to the fifth embodiment.

Additionally, in the solid-state imaging device 1, as illustrated especially in FIG. 15, constructed is a backside illumination type solid-state imaging device including two types of the first photoelectric conversion element PE1 and the second photoelectric conversion element PE2. In such a solid-state imaging device 1, it is possible to effectively suppress or prevent a short circuit between different power supplies.

### 8. Application Example of Application to Moving Object

It is possible to apply the technique of the present disclosure (present technique) to various products. For example, the technique of the present disclosure may be implemented as an apparatus that is mounted on a moving object of any type among an automobile, an electric automobile, a hybrid electric automobile, an autobicycle, a bicycle, a personal mobility, an airplane, a drone, a ship, a robot, and the like.

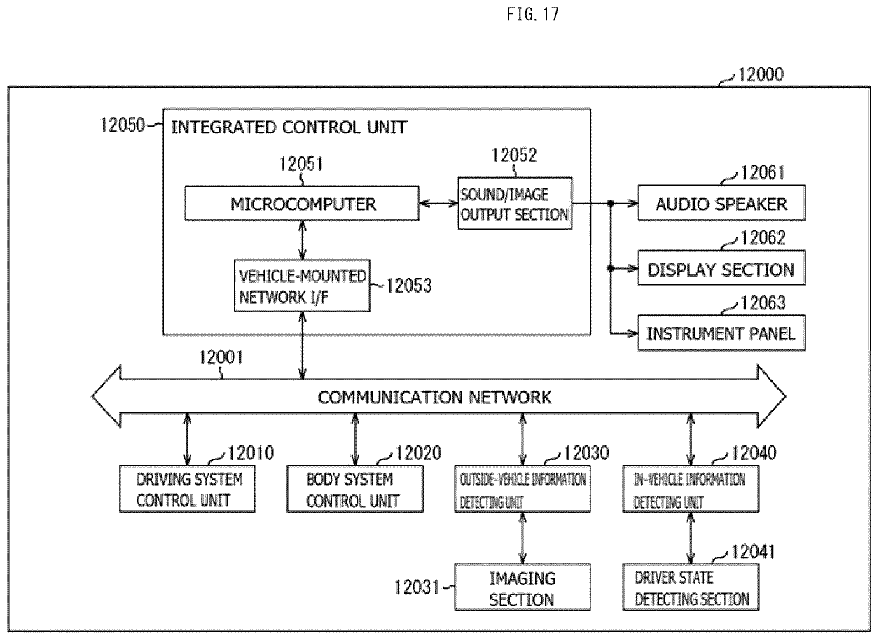

FIG. 17 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 17, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 17, an audio speaker 12061, a display section 12062, and an instrument panel 12063 are illustrated as the output device. The display section 12062 may, for example, include at least one of an on-board display and a head-up display.

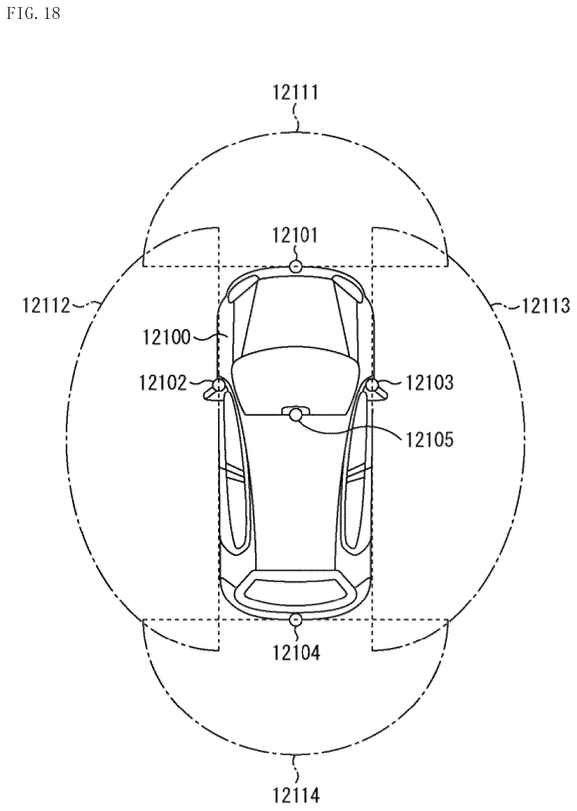

FIG. 18 is a diagram depicting an example of the installation position of the imaging section 12031.

In FIG. 18, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 18 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The example of the vehicle control system to which the technique of the present disclosure is applicable has been described above. The technique of the present disclosure is applicable to the imaging section 12031 out of the above-mentioned configurations. Applying the technique of the present disclosure to the imaging section 12031 makes it possible to effectively suppress or prevent a short circuit between different power supplies via the guard ring.

### 9. Other Embodiments

The present technique is not limited to the above-mentioned embodiments and is changeable in various manners without departing from the gist of the present technique. For example, the solid-state imaging devices according to two or more embodiments out of the solid-state imaging devices according to the above-mentioned first to seventh embodiments may be combined.

Additionally, in the present technique, a plurality of first semiconductor elements may be laminated and mounted in the thickness direction of the first semiconductor element in the solid-state imaging device according to the fourth embodiment. Additionally, in the present technique, at least the fourth semiconductor element may be further mounted on the third semiconductor element in the solid-state imaging device according to the sixth embodiment. Furthermore, in the present technique, the separation insulator may be a separation insulator in which polycrystalline Si as an embedded insulator is embedded via an inorganic insulation material.

The solid-state imaging device according to the first embodiment of the present disclosure includes the semiconductor layer, the insulator, the first guard ring, and the separation insulator. The semiconductor layer includes the first semiconductor region of the first conductivity type, and the second semiconductor region of the second conductivity type in the imaging region in which the plurality of first photoelectric conversion elements that converts light into electric charges is arrayed. The second conductivity type is the opposite type of the first conductivity type. The insulator is disposed on the first surface of the semiconductor layer on the light incident side. The first guard ring is disposed in the insulator along the outer perimeter of the imaging region. The first guard ring includes a metal material, and is electrically coupled to the first semiconductor region of the semiconductor layer. Here, the separation insulator is disposed in the semiconductor layer along the outer perimeter of the imaging region and along the inner perimeter of the first guard ring. The separation insulator electrically separates the first guard ring from the second semiconductor region. As a result, it is possible to effectively suppress or prevent a short circuit between different power supplies when the first semiconductor region, the first guard ring, and the second semiconductor region serve as a short circuit path.

Additionally, in the solid-state imaging device according to the second embodiment of the present disclosure, the carrier layer of the second conductivity type that is shallower in junction depth than the second semiconductor region is formed in a portion of the first surface of the semiconductor layer between the second semiconductor region and the first guard ring in the solid-state imaging device according to the first embodiment. The separation insulator is then formed to have such a depth as to divide at least the carrier layer. This makes it possible for the separation insulator to electrically separate the first guard ring from the carrier layer coupled to the second semiconductor region. As a result, it is possible to effectively suppress or prevent a short circuit between different power supplies when the first semiconductor region, the first guard ring, and the second semiconductor region serve as a short circuit path.

Additionally, in the solid-state imaging device according to the third embodiment of the present disclosure, the separation insulator is disposed so as to penetrate the semiconductor layer from the first surface to the second surface facing the first surface in the solid-state imaging device according to the first embodiment. This makes it possible for the separation insulator to electrically and physically separate the first guard ring from the second semiconductor region. As a result, it is possible to effectively suppress or prevent a short circuit between different power supplies when the first semiconductor region, the first guard ring, and the second semiconductor region serve as a short circuit path.

### Configurations of Present Technique

The present technique includes the following configurations. According to the present technique having the following configurations, in the solid-state imaging device, it is possible to effectively suppress or prevent a short circuit between different power supplies via the guard ring.
(1)

A solid-state imaging device including:

a semiconductor layer including a first semiconductor region of a first conductivity type, and a second semiconductor region of a second conductivity type in an imaging region in which a plurality of first photoelectric conversion elements that converts light into electric charges is arrayed, the second conductivity type being an opposite type of the first conductivity type;

an insulator disposed on a first surface of the semiconductor layer on a light incident side;

a first guard ring that is disposed in the insulator along an outer perimeter of the imaging region, that includes a metal material, and that is electrically coupled to the first semiconductor region of the semiconductor layer; and

a separation insulator that is disposed in the semiconductor layer along the outer perimeter of the imaging region and along an inner perimeter of the first guard ring, and that electrically separates the first guard ring from the second semiconductor region.
(2)

The solid-state imaging device according to (1), in which

a carrier region of the second conductivity type is formed in a portion of the first surface of the semiconductor layer between the second semiconductor region and the first guard ring, the carrier region being shallower in junction depth than the second semiconductor region, and

the separation insulator is formed to have such a depth as to divide at least the carrier region.
(3)

The solid-state imaging device according to (1) or (2), in which the separation insulator is disposed so as to penetrate the semiconductor layer from the first surface to a second surface facing the first surface.
(4)

The solid-state imaging device according to (3), further including a second guard ring that is disposed in the semiconductor layer along an outer perimeter of the first guard ring and disposed so as to penetrate the semiconductor layer from the first surface to the second surface, in which the separation insulator is formed to have a cross-section structure that is same as a cross-section structure of the second guard ring.
(5)

The solid-state imaging device according to (4), in which the second guard ring is disposed along an inner perimeter of a dicing region.
(6)

The solid-state imaging device according to (4) or (5), in which a plurality of the second guard rings is disposed along the outer perimeter of the first guard ring.
(7)

The solid-state imaging device according to any one of (1) to (6), in which the first guard ring includes tungsten (W).
(8)

The solid-state imaging device according to any one of (1) to (7), in which the separation insulator includes at least one kind of an inorganic insulation material that is selected from SiO₂ and SiN.
(9)

The solid-state imaging device according to any one of (1) to (8), in which

the first semiconductor region is an n-type semiconductor region or an n-type semiconductor substrate, and

the second semiconductor region is a p-type semiconductor region or a p-type well region.
(10)

The solid-state imaging device according to any one of (1) to (9), further including:

a pixel in which an optical filter and an optical lens are sequentially disposed with respect to the first surface of the semiconductor layer via the insulator in a region corresponding to one of the plurality of first photoelectric conversion elements; and

a pixel circuit that is disposed on a second surface side facing the first surface of the semiconductor layer, and that processes electric charges transferred from the plurality of first photoelectric conversion elements.
(11)

The solid-state imaging device according to (10), further including a backside illumination structure.
(12)

The solid-state imaging device according to (10) or (11), further including a first semiconductor element that is mounted on the first surface of the semiconductor layer via the insulator and that includes a circuit electrically coupled to the pixel circuit.
(13)

The solid-state imaging device according to (12), in which a plane area of the first semiconductor element is smaller than a plane area of the semiconductor layer when viewed from a thickness direction of the semiconductor layer.
(14)

The solid-state imaging device according to (12) or (13), in which the first semiconductor element is mounted on the semiconductor layer via a bump electrode.
(15)

The solid-state imaging device according to any one of (10) to (14), further including a second semiconductor element that is mounted on the second surface of the semiconductor layer and that includes a circuit electrically coupled to the pixel circuit.
(16)

The solid-state imaging device according to (15), further including a third semiconductor element that is further mounted on the second semiconductor element, and that includes a circuit electrically coupled to the pixel circuit.
(17)

The solid-state imaging device according to any one of (1) to (16), further including a second photoelectric conversion element in the insulator in the imaging region.
(18)

The solid-state imaging device according to (17), in which the second photoelectric conversion element is an organic photoelectric conversion element.

The present application claims the benefit of Japanese Priority Patent Application JP2022-181092 filed with the Japan Patent Office on Nov. 11, 2022, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A solid-state imaging device, comprising:
a semiconductor layer including a first semiconductor region of a first conductivity type, and a second semiconductor region of a second conductivity type in an imaging region in which a plurality of first photoelectric conversion elements that converts light into electric charges is arrayed, the second conductivity type being an opposite type of the first conductivity type;
an insulator disposed on a first surface of the semiconductor layer on a light incident side;
a first guard ring that is disposed in the insulator along an outer perimeter of the imaging region, that includes a metal material, and that is electrically coupled to the first semiconductor region of the semiconductor layer; and
a separation insulator that is disposed in the semiconductor layer along the outer perimeter of the imaging region and along an inner perimeter of the first guard ring, and that electrically separates the first guard ring from the second semiconductor region.

2. The solid-state imaging device according to claim 1, wherein
a carrier region of the second conductivity type is formed in a portion of the first surface of the semiconductor layer between the second semiconductor region and the first guard ring, the carrier region being shallower in junction depth than the second semiconductor region, and
the separation insulator is formed to have such a depth as to divide at least the carrier region.

3. The solid-state imaging device according to claim 1, wherein the separation insulator is disposed so as to penetrate the semiconductor layer from the first surface to a second surface facing the first surface.

4. The solid-state imaging device according to claim 3, further comprising a second guard ring that is disposed in the semiconductor layer along an outer perimeter of the first guard ring and disposed so as to penetrate the semiconductor layer from the first surface to the second surface,
wherein the separation insulator is formed to have a cross-section structure that is same as a cross-section structure of the second guard ring.

5. The solid-state imaging device according to claim 4, wherein the second guard ring is disposed along an inner perimeter of a dicing region.

6. The solid-state imaging device according to claim 4, wherein a plurality of the second guard rings is disposed along the outer perimeter of the first guard ring.

7. The solid-state imaging device according to claim 1, wherein the first guard ring includes tungsten (W).

8. The solid-state imaging device according to claim 1, wherein the separation insulator includes at least one kind of an inorganic insulation material that is selected from SiO₂ and SiN.

9. The solid-state imaging device according to claim 1, wherein
the first semiconductor region comprises an n-type semiconductor region or an n-type semiconductor substrate, and
the second semiconductor region comprises a p-type semiconductor region or a p-type well region.

10. The solid-state imaging device according to claim 1, further comprising:
a pixel in which an optical filter and an optical lens are sequentially disposed with respect to the first surface of the semiconductor layer via the insulator in a region corresponding to one of the plurality of first photoelectric conversion elements; and
a pixel circuit that is disposed on a second surface side facing the first surface of the semiconductor layer, and that processes electric charges transferred from the plurality of first photoelectric conversion elements.

11. The solid-state imaging device according to claim 10, further comprising a backside illumination structure.

12. The solid-state imaging device according to claim 10, further comprising a first semiconductor element that is mounted on the first surface of the semiconductor layer via the insulator and that includes a circuit electrically coupled to the pixel circuit.

13. The solid-state imaging device according to claim 12, wherein a plane area of the first semiconductor element is smaller than a plane area of the semiconductor layer when viewed from a thickness direction of the semiconductor layer.

14. The solid-state imaging device according to claim 12, wherein the first semiconductor element is mounted on the semiconductor layer via a bump electrode.

15. The solid-state imaging device according to claim 10, further comprising a second semiconductor element that is mounted on the second surface of the semiconductor layer and that includes a circuit electrically coupled to the pixel circuit.

16. The solid-state imaging device according to claim 15, further comprising a third semiconductor element that is further mounted on the second semiconductor element, and that includes a circuit electrically coupled to the pixel circuit.

17. The solid-state imaging device according to claim 1, further comprising a second photoelectric conversion element in the insulator in the imaging region.

18. The solid-state imaging device according to claim 17, wherein the second photoelectric conversion element comprises an organic photoelectric conversion element.
